(19) United States
(12) Patent Application Publication
(10) Pub. No.: US 2025/0089402 A1
(43) Pub. Date: Mar. 13, 2025

(54) METHOD FOR POROSIFYING (Al,In,Ga)N/(Al,In,Ga)N MESAS

(71) Applicant: Commissariat à l'Énergie Atomique et aux Énergies Alternatives, Paris (FR)

(72) Inventors: Bernard Aventurier, Grenoble (FR); Marion Douma, Grenoble (FR); François Levy, Grenoble (FR); Carole Pernel, Grenoble (FR); Margaux Audibert, Grenoble (FR); Ilyes Medjahed, Grenoble (FR)

(73) Assignee: Commissariat à l'Énergie Atomique et aux Énergies Alternatives, Paris (FR)

(21) Appl. No.: 18/824,030

(22) Filed: Sep. 4, 2024

(30) Foreign Application Priority Data
Sep. 8, 2023 (FR) 2309451

(51) Int. Cl. H01L 33/16; H01L 33/00; H01L 33/02; H01L 33/32

(52) U.S. Cl. CPC H10H 20/817; H10H 20/0137; H10H 20/811; H10H 20/8215; H10H 20/824; H10H 20/825

(57) ABSTRACT

A method of porosification of a structure including a base substrate covered with (Al,In,Ga)N/(Al,In,Ga)N mesas, including a porosification step during which the (Al,In,Ga)N/(Al,In,Ga)N mesas are electrochemically porosified, during the porosification step, the structure further comprises, between the mesas or between groups of mesas, electrically-conductive lines covered with an electrically-insulating element.

### CROSS REFERENCE TO RELATED APPLICATIONS

This application claims priority to French application number 2309451, filed Sep. 8, 2023. The content of this application is incorporated herein by reference in its entirety.

### TECHNICAL FIELD

The present disclosure generally concerns the field of color microdisplays, and in particular the field of color microdisplays based on micro-LEDs.

The invention concerns a method for porosifying (Al,In,Ga)N/(Al,In,Ga)N mesas.

The invention also concerns a structure thus obtained comprising porosified (Al,In,Ga)N/(Al,In,Ga)N mesas.

### PRIOR ART

Color microdisplays comprise pixels formed of blue, green, and red sub-pixels (RGB pixels). In the rest of the disclosure, these sub-pixels will be more simply designated as pixels, for the sake of brevity.

Blue and green pixels may be manufactured from nitride materials, and red pixels may be manufactured from phosphide materials. To combine on a same substrate these three types of pixels, the pick-and-place technique is generally used. However, in the case of microdisplays with pixels smaller than 10 μm, this technique can no longer be used, not only because of alignment issues, but also because of the time required to implement such a technique at this scale. For screens with a large number of pixels (high definition), this “pick-and-place” technique is problematic in terms of time. Further, the pixels have to be sampled from different wafers, which requires successive transfers. Parallel transfer techniques may also be used (‘mass transfer’).

Another solution comprises performing the color conversion with quantum dots (QDs) or nanophosphors pumped by blue μLEDs originating from a single wafer, either transferred, or in a monolithic array (case preferred for microdisplays). However, the control of the deposition of these materials on pixels of small dimensions is difficult and their flux resistance is not sufficiently robust.

It is thus crucial to be able to obtain the three RGB pixels natively with the same family of materials, and having their growth performed on the same substrate. To achieve this, InGaN is the most promising material. This material can indeed theoretically cover the entire visible spectrum according to its indium concentration. Blue micro-LEDs based on InGaN already have high luminance levels, much higher than their organic counterparts. To emit at wavelengths in green, the quantum wells (QWs) of the LED must contain at least 25% of indium, and for an emission in red, it is necessary to have at least 35% of indium. Unfortunately, the quality of the InGaN material beyond 20% of In is degraded due to the low miscibility of InN into GaN, but also due to the high compressive stress inherent to the growth of the InGaN-on-GaN active area.

It is thus essential to be able to decrease the general stress in GaN/InGaN-based structures.

Currently, one of the most promising solutions comprises porosifying the GaN layer, as described, for example, in the two articles of Pasayat et al. (Materials 2020, 13, 213; Appl. Phys. Lett. 116 111101 (2020)). The method described in these articles comprises the following steps:
providing a stack comprising a sapphire substrate covered with a layer of non-intentionally doped GaN (nid GaN), a layer of n+ doped GaN (5e10¹⁸ at/cm³), and a layer of non-intentionally doped InGaN or GaN,
partially etching the stack to form the GaN/InGaN or GaN/GaN mesas; the thickness of the doped layer is only partially etched so that the residual doped layer at the bottom of the mesa allows the polarization of the doped layer of all mesas (polarization ring or wafer edge polarization, for example)
performing a step of electrochemical porosification in an oxalic acid solution (0.3 M), the doped GaN layer playing the role of an anode and a platinum wire playing the role of a cathode.

The porosified GaN layer thus obtained can enable to grow a LED nitride structure based on InGaN with a better crystal quality, due to the relaxation of the generated porous mesas.

However, the quality of the LED depends not only on the pore diameter, but also on the porosity of the porosified GaN layer. It is thus necessary to be able to homogeneously porosify all the mesas of a same wafer.

It is also possible to have a layer common to all mesas in these stacks. The porosification step is then carried out by polarizing this common layer with an anodic potential.

For example, FIGS. 1A to 1C show different steps of such a method. More particularly, the method comprises the following steps:
providing a stack successively comprising a support layer 10, a non-intentionally doped GaN layer 11, a doped or heavily-doped GaN layer 12, a nid InGaN or GaN layer 13 (FIG. 1A),
structuring mesas in this stack, the mesas comprising the nid InGaN or GaN layer 13 and a portion of the doped or heavily-doped GaN layer 12 (FIG. 1B), the other portion of the doped GaN layer playing the role of a layer common to the mesas,
soaking the resulting structure in an electrolytic solution and applying a voltage between the doped or heavily-doped GaN layer 12 and a counter-electrode, whereby a porosified GaN layer 12′ is obtained (FIG. 1C).

Nid InGaN layers are known to have intrinsic defects (‘V-pits’), which facilitate the porosification of the mesas since the electrolytic solution can permeate from this upper layer 13 of the mesas all the way to the doped or heavily-doped layer 12 through these defects as well as through the flanks of the doped or heavily-doped layer of mesas 12.

However, nid GaN layers do not have such defects: they are dense layers. Thus, in the GaN/GaN configuration, the doped or heavily-doped layer of mesas 12 porosifies from the flanks of mesas to the center of the mesas. This layer does not porosify all the way to the center of the mesas. Wafer edge/center effects are observed, for example on 2-inch wafers. FIGS. 2A and 2B show the mesas of the center of such a structure, after porosification, in cross-section and top view respectively. The mesas are very partially porosified.

This effect may be due to the degradation of the lateral conductivity of the residual doped mesa bottom layer, the polarization occurring from the wafer periphery, whereby the wafer edge/center effect.

There thus exists a real need to have a method enabling to fully porosify mesas and to limit center-edge effects on wafers, particularly on 2-inch (5.08 cm) wafers, and even more so on wafers of greater dimensions (200 mm and 300 mm).

### SUMMARY OF THE INVENTION

There exists a need to provide a method of porosification of (Al,In,Ga)N/(Al,In,Ga)N mesas, enabling to identically (or homogeneously) porosify all the mesas on the wafer, be they are at the edge or at the center of the wafer, the method advantageously having to be usable even for large substrates (typically on substrates having a diameter of at least 5 cm and preferably of at least 10 cm).

This aim is achieved by a method of porosification of a structure comprising a base substrate covered with (Al,In,Ga)N/(Al,In,Ga)N mesas,
the method comprising a porosification step during which the (Al,In,Ga)N/(Al,In,Ga)N mesas are electrochemically porosified,
during the porosification step, electrically-conductive lines covered with an electrically-insulating element being arranged on the base substrate between the mesas or between groups of mesas.

According to an advantageous embodiment, the base substrate comprises a support layer, a first non-doped GaN layer, and a second doped GaN layer.

Preferably, the (Al,In,Ga)N/(Al,In,Ga)N mesas comprise a third layer of heavily-doped (Al,In,Ga)N and a fourth layer of non-doped or lightly-doped (Al,In,Ga)N. A portion of the second doped GaN layer extends in the mesas. During the porosification step, the electrically-conductive lines are in direct contact with the second doped GaN layer.

The third layer of heavily-doped (Al,In,Ga)N mesas is porosified during the porosification step. The third layer of heavily-doped (Al,In,Ga)N mesas may be partly or totally porosified during the porosification step.

According to an advantageous variant, the electrically-conductive lines are made of a metal, preferably of titanium, or of a conductive polymer.

According to another advantageous variant, the electrically-conductive lines are made of heavily-doped GaN.

According to this other advantageous variant, the method may comprise a step during which the electrically-conductive lines are formed by epitaxy.

Advantageously, the electrically-conductive lines form a grid.

Advantageously, the electrically-conductive lines locally cover the base substrate and the space between the electrically-conductive lines and the mesas is in the range from 100 nm to 1 μm, preferably from 200 nm to 500 nm.

An embodiment provides a structure comprising a base substrate covered with porosified (Al,In,Ga)N/(Al,In,Ga)N mesas. The structure further comprises electrically-conductive lines, covered with an electrically-insulating element, arranged on the base substrate between the mesas or between groups of mesas.

Advantageously, the base substrate comprises a support layer, a first non-doped GaN layer, and a second doped GaN layer.

Preferably, the (Al,In,Ga)N/(Al,In,Ga)N mesas comprise a third heavily-doped porosified GaN layer and a fourth non-doped or lightly-doped (Al,In,Ga)N layer. A portion of the second doped GaN layer extends in the mesas.

The third layer of heavily-doped (Al,In,Ga)N mesas may be partly or totally porosified.

According to an embodiment, the electrically-conductive lines are made of heavily-doped GaN, of metal, or of a conductive polymer.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A, 1B, and 1C, previously described, schematically show different steps of a porosification method according to prior art;

FIG. 2A, previously described, is an image obtained with a scanning electron microscope of an (Al,In,Ga)N/(Al,In,Ga)N mesa according to prior art, after the porosification step: the porosification is incomplete,

FIG. 2B, previously described, is an image obtained with a dark-field optical microscope of different (Al,In,Ga)N/(Al,In,Ga)N mesas, in top via, according to prior art, after the porosification step, at the center of the wafer; the left-hand portion of the drawings corresponds to (Al,In,Ga)N/(Al,In,Ga)N mesas having a 3-μm width and the right-hand portion of the drawings corresponds to (Al,In,Ga)N/(Al,In,Ga)N mesas having a 5-μm width,

FIGS. 3A, 3B, and 3C schematically show different steps of a mesa porosification method according to a specific embodiment of the invention;

FIG. 4 shows, schematically and in cross-section, a structure comprising porosified (Al,In,Ga)N/(Al,In,Ga)N mesas and electrically-conductive lines, according to an embodiment of the invention,

FIGS. 5A, 5B, 5C, 5D schematically show different steps of a method of manufacturing a metal grid according to a specific embodiment of the invention;

FIGS. 6A, 6B, 6C, 6D schematically show different steps of a method of manufacturing a metal grid according to another specific embodiment of the invention;

FIGS. 7A, 7B, 7C schematically show different steps of a method for covering a metal grid with an electrically-insulating element according to a specific embodiment of the invention; and

FIGS. 8A, 8B, 8C, 8D, and 8E schematically show different steps of a method of manufacturing a heavily-doped GaN grid, covered with an electrically-insulating element, according to a specific embodiment of the invention.

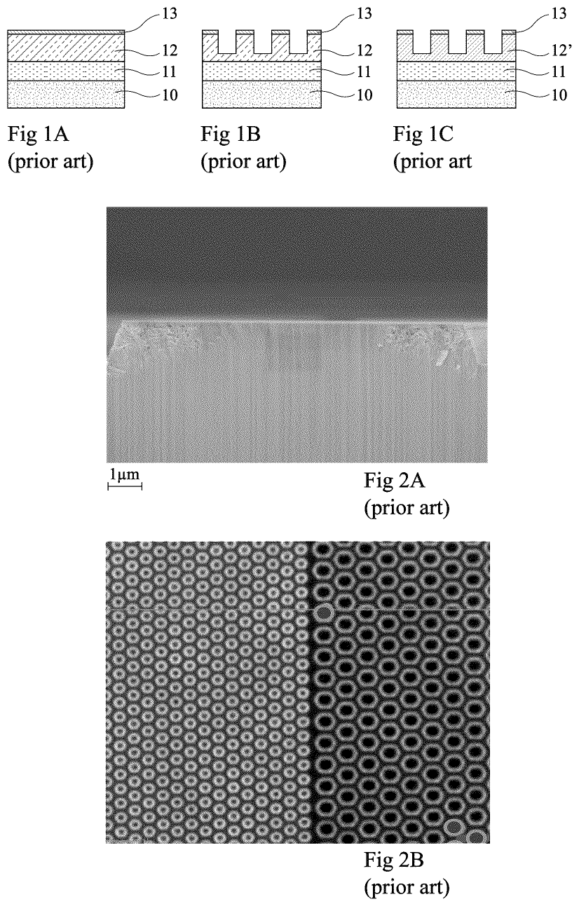

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings or to a . . . in a normal position of use.

Unless specified otherwise, the expressions “about”, “approximately”, “substantially”, and “in the order of” signify plus or minus 10%, preferably of plus or minus 5%.

Although this is by no means limiting, the invention particularly finds applications in the field of color microdisplays, and more specifically for the manufacturing of red-green-blue pixels. However, it may also be used in the field of photovoltaics or also of water splitting, since, on the one hand, InGaN absorbs in the entire visible spectrum and, on the other hand, its valence and conduction bands are around the stability range of water, a thermodynamic condition required for the water splitting reaction. The invention may also be advantageous for the manufacturing of LEDs or of lasers emitting at high wavelengths.

The method is particularly advantageous to manufacture structures comprising porosified (Al,In,Ga)N/(Al,In,Ga)N mesas having, in particular, a pitch smaller than 30 μm.

By (Al,In,Ga)N, there is meant AlN, AlGaN, InGaN, or GaN. Hereafter, it is more specifically referred to porous GaN, but with such a method, it is possible to have, for example, porous InGaN or AlGaN. The dense InGaN layer (compressed) or the dense AlGaN layer (under tension) will relax due to a porous structure, whatever its composition.

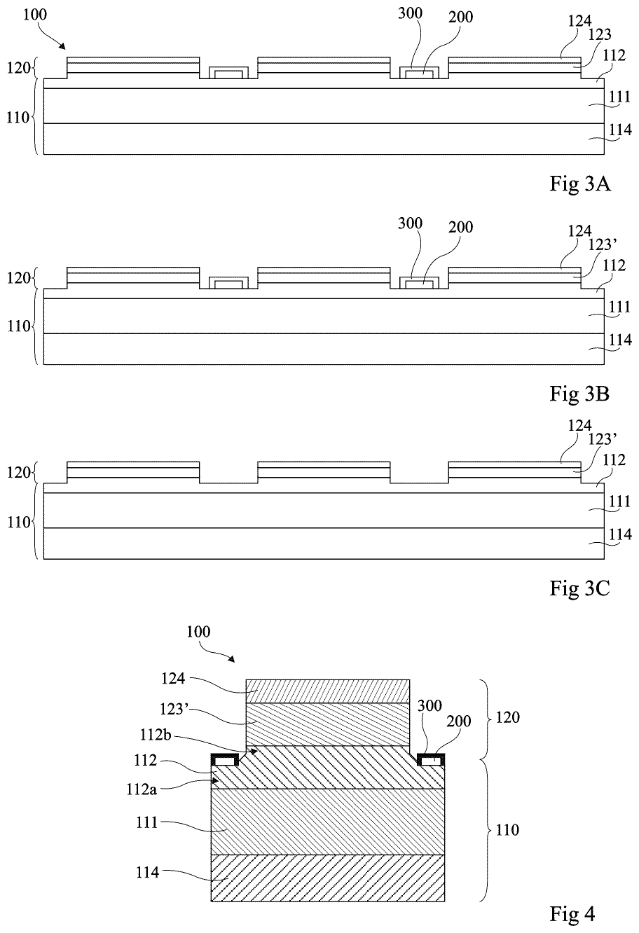

Referring to FIGS. 3A, 3B, and 3C, the method of porosification of (Al,In,Ga)N/(Al,In,Ga)N mesas 120, which comprises the following steps, will now described in more detail:
i) providing a structure 100 comprising a base substrate 110 covered with (Al,In,Ga)N/(Al,In,Ga)N mesas 120, electrically-conductive lines 200 covered with an electrically-insulating element 300 being arranged on base substrate 110 between groups of mesas or between mesas 120 (FIG. 3A),
ii) porosifying mesas 120 (FIG. 3B),
iii) optionally removing electrically-insulating element 300 or removing electrically-conductive lines 200 and insulating element 300 (FIG. 3C).

The use of electrically-conductive lines 300 positioned between mesas 120 enables to obtain a structure in which each mesa 120 has an equivalent electrical configuration (the potential loss is sufficiently low between mesas). The polarization of mesas 120 is homogeneous, resulting in a good control of the porosification of the mesas on each pattern. The method not only enables to identically (or homogeneously) porosify all the mesas 120 on the wafer, whether they are at the edge or at the center of the wafer, but also to porosify the entire volume of the doped layer of mesas 120. It is also possible to control the porosification of mesas 120 so as to leave, for each mesa 120, a non-porosified central area forming an electrical conduction channel within the mesas.

There are no edge-center effects for the porosification. The method is perfectly adapted to patterns having dimensions greater than 5 μm and/or to large substrates (typically on substrates having a diameter of at least 5 cm and preferably at least 10 cm).

Further, the upper layer of substrate 110 in contact with electrically-conductive lines 200 may have a lighter doping since the electrical conduction takes place by means of electrically-conductive lines 200. Thus, not only is the layer less exposed to an unwanted porosification, but the layer also less stressed.

With such a method, the obtained structure exhibits a good crystal quality. There is no risk of porosification of the underlying layers due to defects at the foot of the mesas. Re-epitaxially grown layers can easily be deposited on the structure with no risk of stress resulting in the forming of cracks. The total re-epitaxial thickness may be high.

These lines are covered with an electrically-insulating element which completely covers them and prevents them from being in contact with the electrolyte during the porosification step. Thus, the lines are not damaged during this step; there is no loss of conductivity.

The different steps of the method will now be described in more detail.

As shown in FIG. 3A and in FIG. 4, the base substrate 110 of the structure 100 provided at step i) successively comprises:
a support layer 114,
optionally a (Al,Ga)N buffer layer, particularly in the case of a silicon support layer 114,
a first non-doped GaN layer 111,
a second doped GaN layer 112.

The (Al,In,Ga)N/(Al,In,Ga)N mesas 120 comprise a third heavily-doped (Al,In,Ga)N layer 123 and a fourth non-doped or lightly-doped (Al,In,Ga)N layer 124.

At the end of porosification step ii), the third (Al,In,Ga)N mesa layer 123′ is at least partly (that is, partly or totally) porosified.

A portion 112b of the second doped GaN layer 112 extends in mesas 120. The other portion 112a of the second doped GaN layer 112 forms the upper portion of base substrate 110. This portion is in direct contact with electrically-conductive lines 200. In other words, there is no element between the portion 112a of the second doped GaN layer 112 and electrically-conductive lines 200. The portion 112a of the second 112-doped GaN layer forms the bottom of the mesas.

The bottom of the mesas is preferably preserved from porosification during step ii).

The structure 100 provided at step i) is, for example, obtained by providing and then locally etching a stack successively comprising:
a support layer 114,
optionally, an (Al,Ga)N buffer layer, particularly in the case of a silicon support layer 114,
a first non-doped GaN layer 111,
a second doped GaN layer (GaN n) 112,
a third heavily-doped GaN layer (n+ GaN or nn GaN) 123, and
a fourth layer of non-intentionally doped (nid) or lightly-doped AlN, InGaN, or GaN (noted (Al,In,Ga)N) 124.

Preferably, the stack is formed of the previously-mentioned layers. In other words, it comprises no other layers.

Support layer 114 is, for example, made of sapphire or of silicon.

Support layer 114 has, for example, a thickness in the range from 250 μm to 2 mm. The thickness depends on the nature of support layer 114 and on its dimensions. For example, for a sapphire support layer having a 2-inch diameter, the thickness may be 350 μm. For a sapphire support layer having a 6-inch diameter, the thickness may be 1.3 mm. For a silicon support layer having a 200-mm diameter, the thickness may be 1 mm.

By “from X to Y”, it is meant that the value lies between X and Y, limiting values being included.

In the case of a silicon support layer 114, an (Al,Ga)N buffer layer is advantageously interposed between support layer 114 and nid GaN layer 111.

The first layer 111 is a nid GaN layer. It is a layer which is non-intentionally doped (nid) so as not to be porosified. By non-intentionally doped GaN, there is meant a concentration lower than 1^{e} 17 at/cm³.

The first nid GaN layer 111 for example has a thickness ranging from 500 nm to 5 μm. Advantageously, its thickness is between 1 and 4 μm to absorb the stress associated with the lattice mismatch between GaN and the substrate.

The second layer 112 is a doped GaN layer. By doped GaN, there is meant a concentration, preferably greater than 1·10¹⁷ at/cm³ and preferably lower than 5·10¹⁸ at/cm³ and even more preferably lower than 1·10¹⁸ at/cm³. The presence of the electrically-conductive lines enables to have a GaN layer having a concentration lower than 5·10¹⁷ at/cm³ and, for example, between 1·10¹⁷ at/cm³ and 5·10¹⁷ at/cm³.

The second GaN layer 112 has, for example, a thickness ranging from 200 nm to 1 μm, preferably between 400 and 700 nm. The minimum thickness varies according to the doping level.

The third layer 123 is a heavily-doped GaN layer. By heavily-doped GaN, there is meant a concentration greater than 5·10¹⁸ at/cm³, preferably greater than 8·10¹⁸ at/cm³, or even greater than 10¹⁹ at/cm³. It has, for example, a doping ten times greater than second layer 112. It has a thickness in the range from 200 nm to 2 μm, preferably from 500 nm to 1 μm. Preferably, the doping of third layer 123 is greater by a factor 30 or even by a factor of 100 than the doping of second layer 112.

The fourth layer 124 is an non-intentionally doped or lightly-doped (Al,In,Ga)N layer. By lightly-doped (Al,In,Ga)N, there is meant a doping between 1·10¹⁷ at/cm³ and 5·10¹⁷ at/cm³. By non-doped, there is meant a doping level lower than 1·10¹⁷ at/cm³.

It may be an AlN, AlGaN, InGaN, or GaN layer. It has, for example, a thickness between 10 nm and 200 nm, preferably between 50 nm and 200 nm. The doping is sufficiently low for this layer to be electrically insulating. It is not porosified during step d).

This layer 124 is little or not at all affected by porosification and is used as a seed layer for resuming the growth. This layer 124 is continuous to ensure the quality of the re-epitaxial layer, an (In,Ga)N layer, for example, on the structure.

The dopings of the different above-mentioned layers, and particularly of the second layer 112 and of the third layer 123, will be selected according to the voltage applied during the porosification.

In particular, the respective doping rates are selected so that at a given potential, there is a selectivity between the heavily-doped area and the lightly-doped area. For a given potential, the doping rate of the second layer 112 is selected so that the second layer 112 is not porosified during step d) and the doping rate of the third layer 123 is selected so that the third layer 123 is porosified during step d).

Hereafter, an n-type doping is described, but it could be a p-type doping.

The previously-described stack is structured to form mesas 120, for example, by photolithography.

Mesas 120, also known as elevations, are raised elements. They are obtained, for example, by etching of a continuous layer or of a plurality of stacked continuous layers, so as to only leave a number of “reliefs” of this layer or of these layers. The etching is preferably carried out with a hard mask which features a favorable selectivity with the etch rate of GaN layers (typically with an etch rate ratio >1/4). The hard mask is, for example, made of SiO₂. After etching of the mesas, this hard mask is removed by a wet chemical process before porosification. It is also possible to remove this hard mask after porosification, by only exposing it in the polarization areas used for electrochemical polarization. Advantageously, the mask is removed before the porosification step.

Preferably, the flanks of mesas 120 are perpendicular to this stack of layers.

The surface of the mesas may be circular, hexagonal, square, or rectangular.

The largest surface dimension of mesas 120 ranges from 500 nm to 500 μm. For example, the largest dimension of a circular surface is its diameter.

The thickness of the mesas corresponds to the dimension of the mesa perpendicular to the underlying stack.

The spacing between two consecutive mesas 120 may range from a few micrometers to a few tens of micrometers. The spacing preferably ranges from 50 nm to 20 μm. It is, for example, 5 μm. Even more preferably, it is in the range from 1 to 2 μm.

Mesas 120 may have identical or different doping levels. The higher the doping level, the greater the porosification will be for a fixed potential. The relaxation of the fourth layer 124 of dense (Al,In,Ga)N depends on the porosification rate of the mesas. Thus, different quantities of indium may be incorporated during the re-epitaxy of InGaN on dense layer 124 (due to the reduction of the compositional pulling effect (that is, the pushing of In atoms towards the surface, preventing them from incorporating into the layer). One will thus obtain, after epitaxy of the complete LED structure, blue, green, and red (RGB) mesas on a same substrate, and in a single growth step, if the distance between the relaxation levels of the mesas is sufficient.

Mesas 120 are formed by etching the stack, and more particularly, by etching fourth layer 124, third layer 123, and a first portion 112a of the second doped layer 112. By stopping the etching in the doped layer, the entire height of the third n++ layer 123 is available for relaxation.

Thus, a structure 100 comprising a base substrate 110 topped with a plurality of (Al,In,Ga)N/(Al,In,Ga)N mesas 120 is obtained.

Each mesa 120 successively comprises from the base: the second portion 112b of doped GaN layer 112, the third heavily-doped GaN layer 123, and the fourth non-doped or lightly-doped (Al,In,Ga)N layer 124.

As a non-limiting illustration, structure 100 may comprise:
a base substrate 110 successively comprising: a sapphire or silicon support layer 114, optionally an (Al,Ga)N buffer layer, a first non-doped GaN layer 111 of 4 μm, a first portion 112a of the second doped GaN layer 112 of 500 nm (1·10¹⁸ at/cm³),
mesas 120 (Al,In,Ga)N/(Al,In,Ga)N successively comprising: a second portion 112b of the second doped GaN layer 112 of 100 nm (1·10¹⁸ at/cm³), a third heavily-doped GaN layer 123 of 800 nm (1·10¹⁹ at/cm³), and a nid layer (Al,In,Ga)N of 100 nm.

Structure 100 further comprises electrically-conductive lines 200 positioned between mesas 120, on base substrate 110. During the porosification, charges flow through the electrically-conductive lines 200 and are injected close to each mesa 120. The distance between electrically-conductive lines 200 and mesas 120 is selected to be sufficiently small to avoid the porosification of the second doped layer 112. It may be adapted to control the desired porosification rate of the mesas.

By electrically conductive, there is meant a conductivity capable of allowing, for example, a current density in the order of 8 mA/cm².

Electrically-conductive lines 200 follow the bottom of mesas 120. Electrically-conductive lines 200 may be straight lines (particularly in the case of square mesas) or broken lines (for example in the case of hexagonal mesas).

Electrically-conductive lines 200 advantageously form a grid, that is, the lines intersect. Each mesa 120 is advantageously positioned next to one or a plurality of electrically-conductive lines 200. By next to, there is meant that at least one space between mesas adjacent to a mesa 120 is covered with an electrically-conductive line 200. Preferably, at least two and even more preferably at least four (for example six) spaces between mesas adjacent to a mesa are covered with lines.

It is also possible to position electrically-conductive lines 200 around groups formed of a plurality of mesas. It is for example possible to form groups of 4 mesas or more.

Electrically-conductive lines 200 may locally or totally cover the bottom of the mesas. They do not form part of mesas 120 or of base substrate 110.

Electrically conductive lines 200 have, for example, a width in the range from 750 nm to 2 μm.

The width of electrically-conductive lines 200 is selected according to the space between mesas. For example, for a space between mesas (‘trench’) of 1.5 μm, lines having a 1-μm width may be selected.

The thickness of electrically-conductive lines 200 is, for example, in the range from 100 to 200 nm.

The dimensions and the thickness will be selected according to the material and to the desired conductivity.

Electrically-conductive lines 200 locally cover base substrate 110, and the gap between electrically-conductive lines 200 and mesas 120 is in the range from 100 nm to 1 μm, preferably from 200 nm to 500 nm.

According to a first advantageous embodiment, electrically-conductive lines 200 are made of metal, for example selected from among titanium and aluminum. Preferably, electrically-conductive lines 200 are made of titanium.

According to a second alternative embodiment, electrically-conductive lines 200 are made of heavily-doped (Al,In,Ga)N, preferably heavily-doped GaN. By heavily-doped, there is meant a concentration greater than 5·10¹⁸ at/cm³.

According to a third alternative embodiment, electrically-conductive lines 200 are made of an electrically-conductive polymer.

Electrically-conductive lines 200 are covered with an electrically-insulating element 300. Electrically-insulating element 300 is chemically inert in the solution used for the porosification. Electrically-insulating element 300 completely covers electrically-conductive lines 200 so that they are not in contact with the electrolyte during the porosification step. Electrically-insulating element 300 is not porosified. Electrically-insulating element 300 is, preferably, a dielectric material. For example, electrically-insulating element 300 is made of silicon oxide (SiO₂) or of silicon nitride (SiN₃₄). It may also be made of a polymer, for example a photosensitive polymer.

According to the nature of electrically-conductive lines 200, a plurality of manufacturing steps may be implemented.

As an illustration, two alternative embodiments for forming electrically-conductive metal lines 200 will be described.

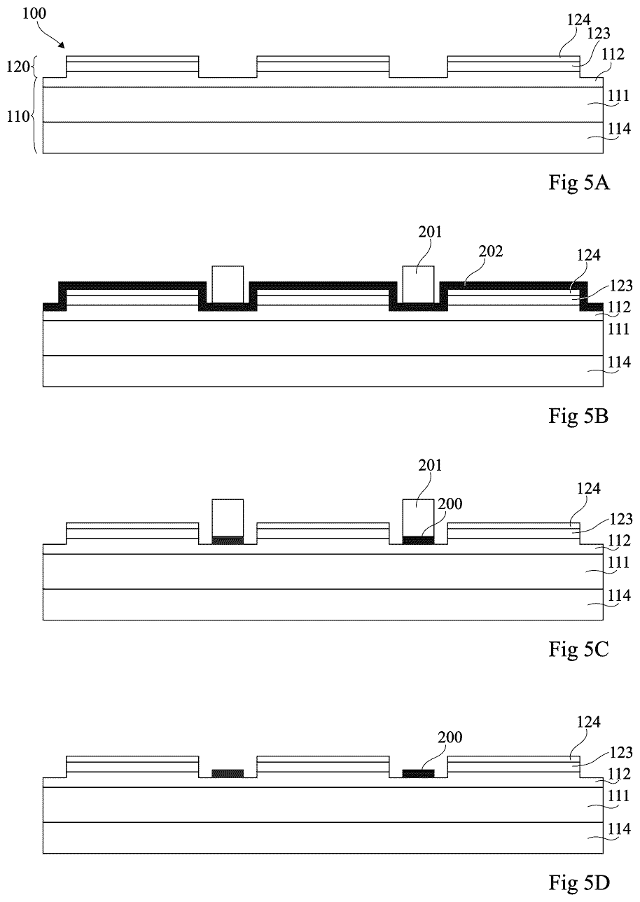

FIGS. 5A to 5D show a first alternative embodiment. The first alternative embodiment comprises the following steps:
providing structure 100 (FIG. 5A),
forming a metal layer 202 all over the wafer surface (that is, metal layer 202 covers mesas 120 and the space between mesas 120), and then depositing a resin 201 between mesas 120, the resin layer 201 having the shape of the lines which are desired to be formed (FIG. 5B),
etching the metal layer 202 not covered with resin layer 201 (FIG. 5C),
removing resin 201 (“stripping”), whereby electrically-conductive metal lines 200 located between mesas 120 (FIG. 5D) are obtained.

Resin 201 defines the grid pattern. It may be formed by photolithography or by silk screening.

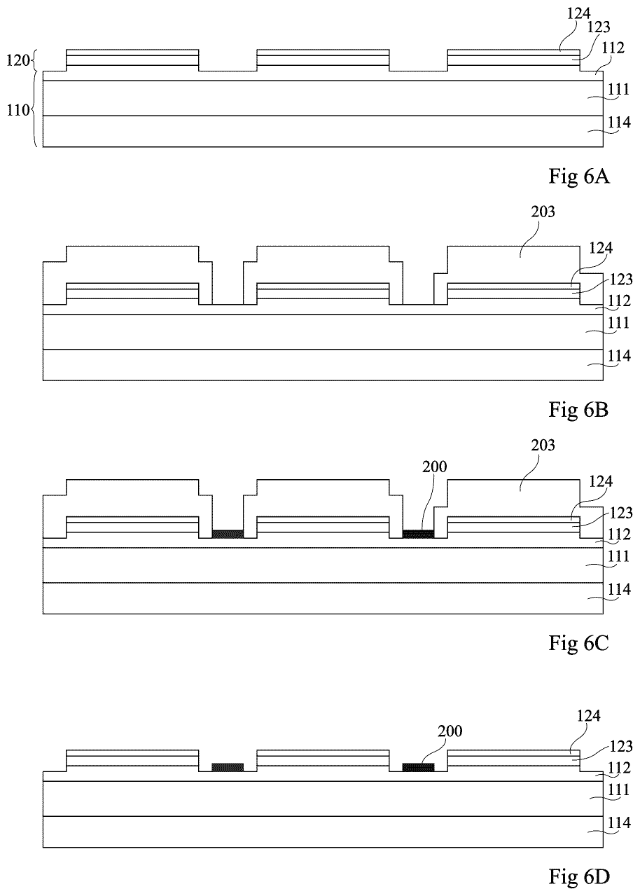

FIGS. 6A to 6D show a second alternative embodiment. The second alternative embodiment comprises the following steps:
providing structure 100 (FIG. 6A),
forming by lithography a resin layer 203 on mesas 120 and locally between mesas 120, so as to have an area between mesas not covered with the resin 203, the uncovered area having the shape of lines, particularly of intersecting lines, preferably a grid shape (FIG. 6B),
depositing a metal layer 200 on the area not covered with resin 203, metal layer 200 thus having the shape of lines, preferably a grid shape (FIG. 6C),
removing resin 203 (“metal lift off by stripping”), whereby electrically-conductive metal lines 200 located between mesas 120 are obtained (FIG. 6D).

The metal layer may be deposited all over the wafer surface.

According to another variant, not shown, electrically-conductive lines 200 are made of a conductive polymer. The conductive polymer may be deposited by silk screening, lithography (exposure-development), or by any other means enabling to form lines with this material.

After porosification, the electrically-conductive polymer lines 200 may be removed by wet etching and/or by dry etching.

Whichever alternative embodiment is implemented, an electrically-insulating element 300 is then deposited on electrically-conductive lines 200 so as to protect them during the anodizing step.

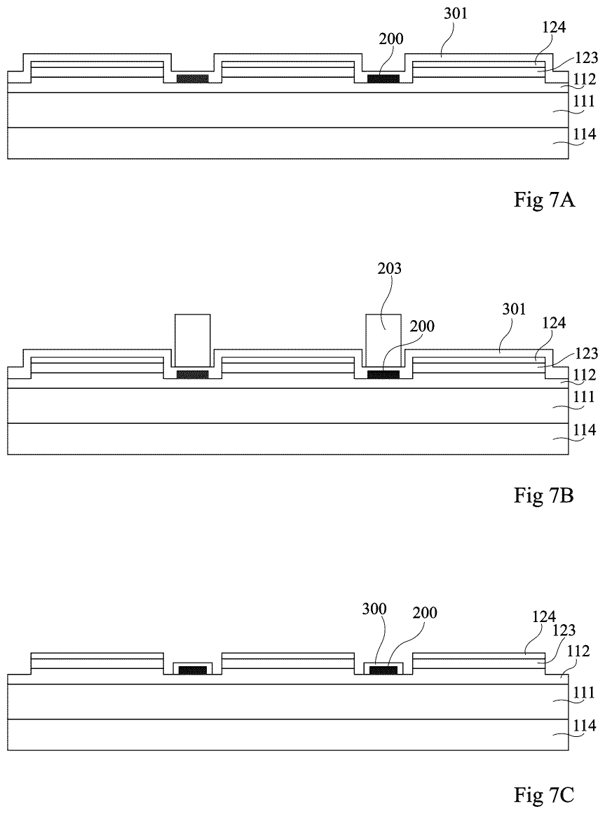

To achieve this, as shown in FIGS. 7A to 7C, it is possible to carry out the following steps:
depositing an electrically-insulating layer 301 (FIG. 7A) all over the wafer surface,
locally depositing a resin 203 opposite electrically-conductive lines 200 (FIG. 7B),
etching the electrically-insulating layer 301 not covered with resin 203, and then removing resin 203 (FIG. 7C).

To form electrically-conductive lines 200 made of doped GaN (typically with a doping level higher than 1·10¹⁸ at/cm³), an area of selective area growth (SAG) may be formed, for example. The growth area is delimited by an SAG layer made of a material unfavorable to the growth of GaN. The SAG layer covers mesas 120 and locally covers the space between mesas. The SAG layer has an opening in the form of lines, preferably in the form of a grid, delimiting an uncovered area on which the doped GaN grid is desired to be formed. The SAG layer has a shape complementary to the grid.

By unfavorable to the growth of GaN, there is meant that GaN cannot grow on this layer, or that the kinetics of GaN growth on this material are very slow as compared with the kinetics of GaN growth on the material accessible through the openings of the SAG layer (that is, the material of the space between mesas, that is, the material forming second layer 112: doped GaN).

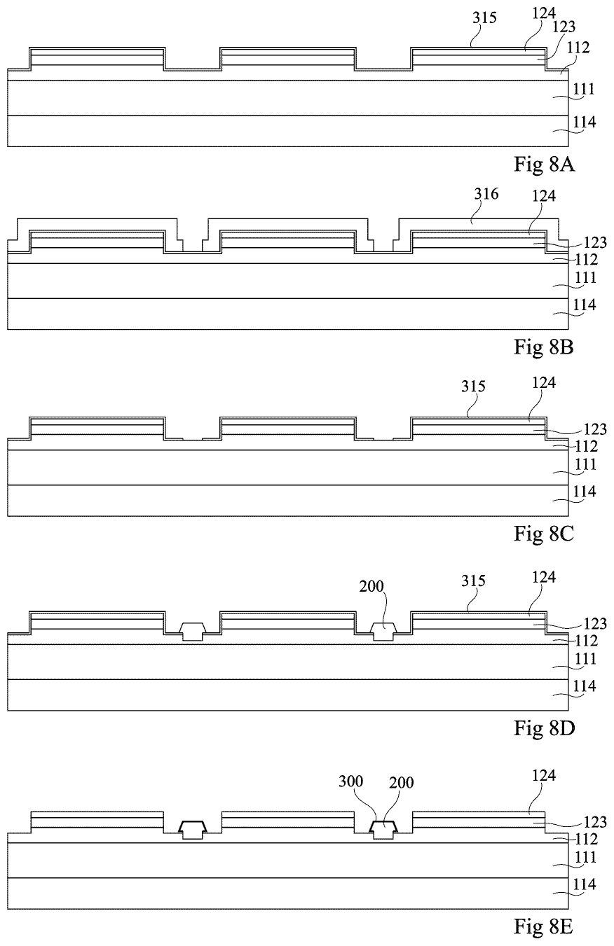

More particularly, to form electrically-conductive doped GaN lines 200, it is possible to carry out the following steps (FIGS. 8A to 8D):
depositing all over the wafer surface a layer 315 made of a material unfavorable to the growth of GaN, for example a nitride or an oxide, in particular a silicon nitride and/or a silicon oxide (FIG. 8A),
locally depositing a resin 316 by lithography, so as to leave part of the layer 315 made of a material unfavorable to GaN growth accessible between the mesas (FIG. 8B),
then etching said material 315, and removing resin 316, whereby a selective growth area having the shape of lines between the mesas is obtained (FIG. 8C),
growing by epitaxy n+-doped GaN to form electrically-conductive lines 200 made of n+-doped GaN between the mesas (FIG. 8D).

Layer 315 is then removed.

As previously, an electrically-insulating element 300 is then deposited on the electrically-conductive lines 200 to protect them during the anodizing step (FIG. 8E). For example, the previously-described steps shown, in particular, in FIGS. 7A to 7C, may be carried out.

In particular, they may be the following steps:
depositing all over the wafer surface an electrically-insulating layer (for example made of a dielectric material),
locally depositing a resin opposite the electrically-conductive lines,
etching the electrically-insulating layer not covered with the resin,
removing the resin.

At step ii), the structure is porosified. The porosification may be carried out according to the following sub-steps:
electrically coupling structure 100 and a counter-electrode to a voltage or current generator,
soaking structure 100 and the counter-electrode in an electrolytic solution,
applying a voltage or a current between the second doped GaN layer 112 and the counter-electrode so as to porosify the third heavily-doped (Al,In,Ga)N layer 123 of mesas 120.

Structure 100 and a counter-electrode (CE) are electrically coupled to a voltage or current generator. The device plays the role of a working electrode (WE). Hereafter, it will be referred to as a voltage generator, but it may be a current generator enabling to apply a current between the device and the counter-electrode.

The contacting area is formed on structure 100.

In particular, the contacting area may be formed on base substrate 110. The contacting may be performed on second doped GaN layer 112. The contacting may be performed on the bottom of the mesas, at the level of second layer 112, which enables to use the etching step to also form the contacting areas. Alternatively, the contacting may be performed on electrically-conductive lines 200.

It is also possible to make contact on one of the other layers: on the fourth layer of lightly-doped (Al,In,Ga)N 124 or on the third layer of heavily-doped (Al,In,Ga)N 123. In the case of a contacting on the heavily-doped layer, its opening will advantageously be limited to an area preserved from the electrolyte.

The contacting area may also be topped with a metal layer to improve the contact for electrochemical polarization. This contact may be removed after the porosification before resuming the epitaxy.

The counter-electrode is made of an electrically-conductive material, such as for example a metal with a large developed surface area and inert to the chemistry of the electrolyte, such as a platinum mesh.

The electrodes are soaked in an electrolyte, also known as an electrolyte bath or electrolyte solution. The electrolyte may be acidic or basic. The electrolyte is, for example, oxalic acid. It may also be KOH, HF, HNO₃, NaNO₃, or H₂SO₄.

The voltage applied between structure 100 and the counter-electrode may range from 1 to 30 V, for example. Preferably, it is from 5 to 15 V, and even more preferably from 6 to 12 V, for example from 8 to 10 V. The voltage is selected according to the doping levels of the different layers, in order to obtain the desired selectivity. It is applied, for example, for a period ranging from a few seconds to several hours. The porosification is complete when there is no further current at an imposed potential. At that time, the entire doped structure is porosified and the electrochemical reaction stops.

For example, the porosification step is carried out by applying a 9-V voltage (non-pulsed) in an oxalic acid solution. The stopping of the method is controlled with the current drop.

The electrochemical anodizing step may be performed under ultraviolet (UV) light.

Advantageously, the porosification takes place all throughout the volume of the third layer of heavily-doped GaN 123.

According to another advantageous embodiment, only part of the volume of the third layer of heavily-doped GaN 123 is porosified. It is possible to stop the porosification step before having completely porosified the third layer of heavily-doped GaN 123. It is for example possible to leave a conductive channel at the center of the mesas, for example.

At the end of the porosification step, the porosity rate of the third heavily-doped GaN layer 123 is, advantageously, at least 10%. It preferably ranges from 25% to 70%, more preferably from 25% to 50%, for example from 45% to 50%.

The largest dimension (the height) of the pores may vary from a few nanometers to a few micrometers. The smallest dimension (the diameter) may vary from a few nanometers to some hundred nanometers, in particular from 30 to 70 nm.

The obtained porosification (porosity rate and pore size) depends on the doping of the layer and on the parameters of the method (applied voltage, duration, nature, and concentration of the electrolyte, chemical post-treatment or anneal). The porosification variation enables to control the incorporation/segregation rate. The porosification, and in particular the pore size, may subsequently vary, when the epitaxy is resumed, according to the temperature applied.

The mesas 120 of a same plate are thus porosified, be it for substrates of small or medium dimensions, or for substrates of large dimensions.

The feet of the mesas are intact.

The obtained structure is shown in FIG. 3B and in FIG. 4.

The method may comprise a step iii) during which the electrically-conductive lines as well as the electrically-insulating element are removed (FIG. 3C).

Advantageously, the electrically-conductive lines are removed when they are made of metal or of a conductive polymer. This prevents any contamination during a subsequent further epitaxy.

According an advantageous alternative embodiment, the lines are made of doped GaN and are kept. It is possible to keep or to remove the insulating element. The presence of electrically-conductive lines is particularly advantageous in the case of a structure of large-scale type. They may advantageously play a role in the final device, for example, in the operation of a large-scale display. Indeed, This enables to avoid any loss of potential between the edge and the center, and to have a homogeneous contacting layer over the entire surface of the structure.

Advantageously, the method comprises a subsequent step iv) during which an epitaxy is performed on mesas 120, whereby an at least partially relaxed, and preferably fully relaxed, epitaxial layer is obtained.

The relaxation rate corresponds to:

Δa/a=(a_{c2}−a_{c1})/a_{c1}
with a_{c1} the mesh parameter of the initial layer having epitaxy resumed thereon (that is, the mesh parameter of layer 124), and
a_{c2} the mesh parameter of the relaxed layer,

The layer is 100% relaxed if a_{c2} corresponds to the mesh parameter of the solid material, of same composition as the re-epitaxially grown layer.

When a_{c1}=a_{c2} the layer is said to be stressed.

By partially relaxed, there is meant a relaxation rate greater than 50%.

Re-epitaxy may be used, for example, to form re-epitaxially grown LEDs.

Re-epitaxy is performed on the fourth nid or lightly-doped (Al,In,Ga)N/(Al,In,Ga)N layer 124 of mesas 120. Since this layer is not porosified during the electrochemical anodizing step, it remains continuous and dense. The re-epitaxy is thus facilitated and the epitaxial layer has an improved durability. The creation of defects due to pore coalescence is avoided.

The layer epitaxially grown during this step iv) is, advantageously, made of gallium nitride or of indium gallium nitride.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Method of porosification of a structure comprising a base substrate covered with (Al,In,Ga)N/(Al,In,Ga)N mesas, comprising a porosification step during which the (Al,In,Ga)N/(Al,In,Ga)N mesas are electrochemically porosified wherein, during the porosification step, electrically-conductive lines covered with an electrically-insulating element are arranged on the base substrate between the mesas or between groups of mesas.

2. Method according to claim 1, wherein the base substrate comprises a support layer, a first non-doped GaN layer, a second doped GaN layer,
the (Al,In,Ga)N/(Al,In,Ga)N mesas comprising a third heavily-doped (Al,In,Ga)N layer and a fourth non-doped or lightly-doped (Al,In,Ga)N layer,
a portion of the second doped GaN layer extending in the mesas,
during the porosification stage, the electrically-conductive lines being in direct contact with the second doped GaN layer
the third heavily-doped (Al,In,Ga)N layer being porosified during the porosification step.

3. Method according to claim 1, wherein the electrically-conductive lines are made of a metal, preferably of titanium, or of a conductive polymer.

4. Method according to claim 1, wherein the electrically-conductive lines are made of heavily-doped GaN.

5. Method according to claim 1, wherein the method comprises a step during which the electrically-conductive lines are formed by epitaxy.

6. Method according to claim 1, wherein the electrically-conductive lines form a grid.

7. Method according to claim 1, wherein the electrically-conductive lines locally cover the base substrate and wherein the space between the electrically-conductive lines and the mesas is in the range from 100 nm to 1 μm, preferably from 200 nm to 500 nm.

8. Structure comprising a base substrate covered with porosified (Al,In,Ga)N/(Al,In,Ga)N mesas,
the structure further comprising electrically-conductive lines, covered with an electrically-insulating element, arranged on the base substrate between the mesas or between groups of mesas.

9. Structure according to claim 8, wherein the base substrate comprises a support layer, a first non-doped GaN layer, and a second doped GaN layer,
the (Al,In,Ga)N/(Al,In,Ga)N mesas comprising a third heavily-doped porosified GaN layer and a fourth non-doped or lightly-doped (Al,In,Ga)N layer,
a portion of the second doped GaN layer extending in the mesas.

10. Structure according to claim 8, wherein the electrically-conductive lines are made of heavily-doped GaN, of metal, or of a conductive polymer.
